(19) United States
(12) Patent Application Publication
(10) Pub. No.: US 2023/0209946 A1
(43) Pub. Date: Jun. 29, 2023

(54) Organic Light Emitting Diode Display

(71) Applicant: LG Display Co., Ltd., Seoul (KR)

(72) Inventor: Keum-Kyu Min, Paju-si (KR)

(21) Appl. No.: 17/992,222

(22) Filed: Nov. 22, 2022

(30) Foreign Application Priority Data
Dec. 23, 2021 (KR) 10-2021-0185951

(51) Int. Cl. H01L 51/00

(52) U.S. Cl. CPC H01L 27/3213; H01L 27/3262; H01L 51/5253

(57) ABSTRACT

An organic light emitting diode display includes: a substrate including a plurality of sub-pixels, the plurality of sub-pixels comprising a red sub-pixel, a green sub-pixel, and a blue sub-pixel; a thin film transistor on the substrate; a first overcoat layer on the thin film transistor, the first overcoat layer including a plurality of micro lenses at a surface of the first overcoat layer; a second overcoat layer on the first overcoat layer and having a flat surface, the second overcoat layer including refractive particles dispersed within the second overcoat layer; and a light emitting diode on the second overcoat layer.

### CROSS REFERENCE TO RELATED APPLICATION

The present application claims the priority benefit of Republic of Korea Patent Application No. 10-2021-0185951 filed in Republic of Korea on Dec. 23, 2021, which is hereby incorporated by reference in its entirety.

### BACKGROUND

### Field of Technology

The present disclosure relates to an organic light emitting diode display, and particularly, relates to an organic light emitting diode display which improves light extraction efficiency.

### Discussion of the Related Art

Recently, as society enters a full-fledged information age, interest in information displays that process and display a large amount of information has been increased, and as a demand for using portable information media has been increased, various lightweight and thin flat displays have been developed and been in the spotlight.

Among various flat displays, in an organic light emitting diode display, a significant portion of light emitted from an organic light emitting layer is lost in the process of passing through various components of the organic light emitting diode display and being emitted to outside the display. The light emitted to the outside of the organic light emitting diode display accounts for about 20% of the light produced in the organic light emitting layer.

Since an amount of light emitted from the organic light emitting layer is increased along with an amount of current applied to the organic light emitting diode display, it is possible to increase a luminance of the organic light emitting diode display by applying more current to the organic light emitting diode display. However, this increases power consumption and also reduces a lifetime of the organic light emitting diode display.

### SUMMARY

Accordingly, the present disclosure is directed to an organic light emitting diode display that substantially obviates one or more of the problems due to limitations and disadvantages of the related art. In order to improve a light extraction efficiency of the organic light emitting diode display, a method of attaching a micro lens array (MLA) to an outside of a substrate of the organic light emitting diode display or forming a micro lens at an overcoat layer of the organic light emitting diode display is disclosed.

An advantage of the present disclosure is to provide an organic light emitting diode display which can extract light trapped inside an element to an outside even when introducing a micro lens array to an outside of a substrate or forming a micro lens inside the display, and thus can improve a light extraction efficiency and increase a lifetime.

Another advantage of the present disclosure is to provide an organic light emitting diode display which can prevent or at least reduce an occurrence of a rainbow mura (or rainbow stain) that may reduce visibility and cause eye fatigue.

Another advantage of the present disclosure is to provide an organic light emitting diode display which can improve a contrast ratio by minimizing a decrease in a visibility of a black color due to a high reflectance.

Another advantage of the present disclosure is to provide an organic light emitting diode display which can realize an image of an excellent color sensitivity.

Additional features and advantages of the disclosure will be set forth in the description which follows, and in part will be apparent from the description, or may be learned by practice of the disclosure. These and other advantages of the disclosure will be realized and attained by the structure particularly pointed out in the written description and claims hereof as well as the appended drawings.

To achieve these and other advantages and in accordance with the purpose of the present disclosure, as embodied and broadly described herein, an organic light emitting diode display includes: a substrate including a plurality of sub-pixels, the plurality of sub-pixels comprising a red sub-pixel, a green sub-pixel, and a blue sub-pixel; a thin film transistor on the substrate; a first overcoat layer on the thin film transistor, the first overcoat layer including a plurality of micro lenses at a surface of the first overcoat layer; a second overcoat layer on the first overcoat layer and having a flat surface, the second overcoat layer including refractive particles dispersed within the second overcoat layer; and a light emitting diode on the second overcoat layer.

In one embodiment, a display device comprises: a substrate including a plurality of subpixels, the plurality of subpixels including a first subpixel configured to emit light of a first color, a second subpixel configured to emit light of a second color, and a third subpixel configured to emit light of a third color; a thin film transistor on the substrate; a first overcoat layer on the thin film transistor; a second overcoat layer on the first overcoat layer, the second overcoat layer including refractive particles dispersed within the second overcoat layer; and a light emitting diode on the second overcoat layer, wherein the refractive particles include first refractive particles that overlap the first sub-pixel and have a first diameter, second refractive particles that overlap the second sub-pixel and have a second diameter, and third refractive particles that overlaps the third sub-pixel and have a third diameter, wherein at least one of the first diameter, the second diameter, and the third diameter is different from another one of the first diameter, the second diameter, and the third diameter.

It is to be understood that both the foregoing general description and the following detailed description are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this specification, illustrate embodiments of the disclosure and together with the description serve to explain the principles of the disclosure. In the drawings:

FIG. 1 is a plan view illustrating a plurality of sub-pixels of an organic light emitting diode display according to an embodiment of the present disclosure;

FIG. 2 is a cross-sectional view illustrating one sub-pixel of an organic light emitting diode display according to an embodiment of the present disclosure;

FIG. 3 is an enlarged picture of a micro lens according to an embodiment of the present disclosure;

FIG. 4 is a view showing an experimental result of measuring a light extraction efficiency and a lifetime according to presence or absence of a second overcoat layer on a first overcoat layer provided with the micro lens;

FIG. 5A is a picture of measuring a rainbow mura of a general organic light emitting diode display;

FIG. 5B is a picture of measuring a rainbow mura of an organic light emitting diode display according to an embodiment of the present disclosure

FIG. 6 is a cross-sectional view, taken along a line V-V’, schematically illustrating sub-pixels according to an embodiment of the present disclosure;

FIG. 7 is a schematic view illustrating a state in which a light is scattered by a high refractive particle according to an embodiment of the present disclosure;

FIG. 8 is a view showing experimental results of measuring a rainbow mura and a visibility of a black color;

FIGS. 9A to 9F are graphs simulating a Mie-scattering effect of a high refractive particle for a blue light according to an embodiment of the present disclosure;

FIGS. 10A to 10F are graphs simulating a Mie-scattering effect of a high refractive particle for a green light according to an embodiment of the present disclosure; and

FIGS. 11A to 11F are graphs simulating a Mie-scattering effect of a high refractive particle for a red light according to an embodiment of the present disclosure.

### DETAILED DESCRIPTION

Hereinafter, an embodiment according to the present disclosure is explained with reference to the drawings.

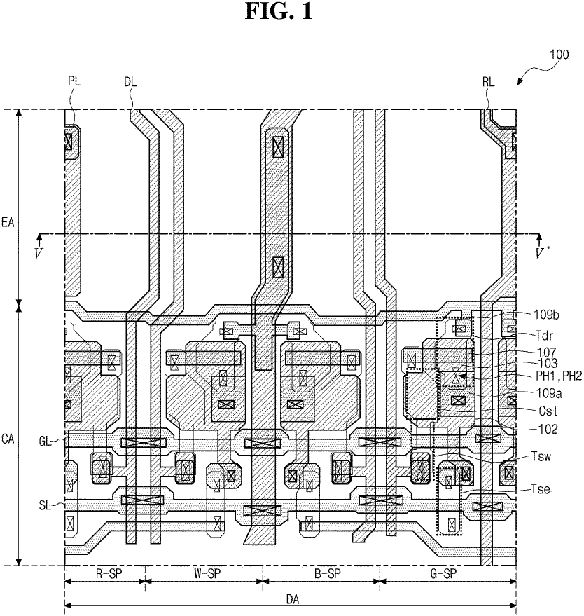

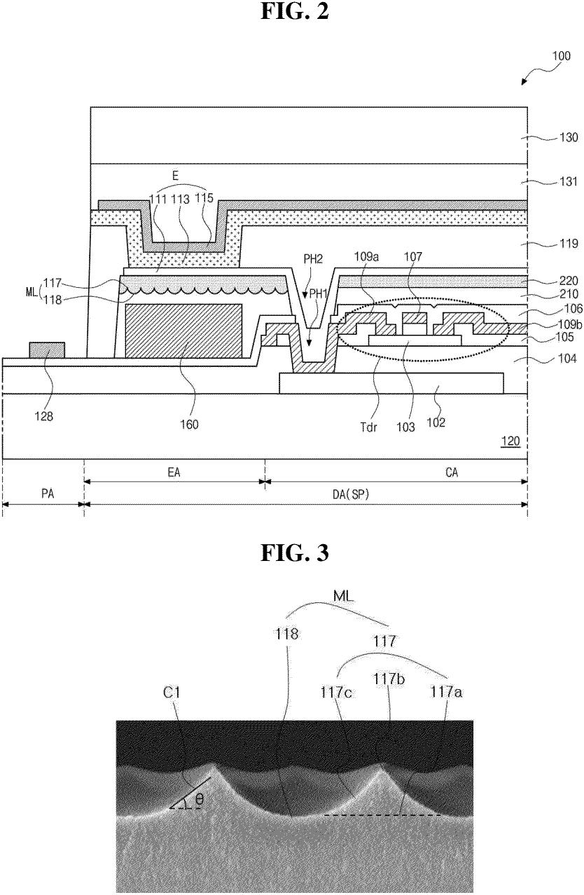

FIG. 1 is a plan view illustrating a plurality of sub-pixels of an organic light emitting diode display according to an embodiment of the present disclosure, and FIG. 2 is a cross-sectional view illustrating one sub-pixel of an organic light emitting diode display according to an embodiment of the present disclosure. In this disclosure, a bottom emission type organic light emitting diode display is described as an example.

FIG. 3 is an enlarged picture of a micro lens according to an embodiment of the present disclosure.

FIG. 5A is a picture of measuring a rainbow mura of a general organic light emitting diode display, and FIG. 5B is a picture of measuring a rainbow mura of an organic light emitting diode display according to an embodiment of the present disclosure.

As shown in FIGS. 1 and 2, the organic light emitting diode display 100 according to the embodiment of the present disclosure may include a substrate 120, a switching thin film transistor Tsw, a driving thin film transistor Tdr, and a sensing thin film transistor Tse, a storage capacitor Cst, and a light emitting diode E.

Specifically, the substrate 120 may include a display area DA and a pad area PA disposed around the display area DA. The display area DA may include a plurality of sub-pixels R-SP, W-SP, B-SP and G-SP, and the plurality of sub-pixels R-SP, W-SP, B-SP and G-SP may each include an emission area EA and a circuit area CA.

The plurality of sub-pixels R-SP (e.g., a first sub-pixel), G-SP (e.g., a second sub-pixel), B-SP (e.g., a third sub-pixel), and a W-SP (e.g., a fourth sub-pixel), may emit red light (e.g., a first color), green light (e.g., a second color), blue light (e.g., a third color), and white light (e.g., a fourth color), respectively.

The sub-pixel SP of FIG. 2 may be any one of the plurality of sub-pixels R-SP, W-SP, B-SP and G-SP of FIG. 1.

A light blocking layer 102 and a first capacitor electrode (not shown) may be disposed in the circuit area CA of each of the sub-pixels R-SP, W-SP, B-SP and G-SP of the display area DA. A pad 128 may be disposed in the pad area PA. A data line DL, a power line PL and a reference line RL may be disposed at boundaries between the sub-pixels R-SP, W-SP, B-SP and G-SP.

The pad 128 may be a gate pad connected to the gate line GL or a data pad connected to the data line DL.

In this case, an anti-reflective layer (not shown) may be further provided below the light blocking layer 102 and the first capacitor electrode. The anti-reflective layer may include molybdenum oxide tantalum (MoOx:Ta), and may have a specific resistance of about 40 milliohm/cm (mΩcm).

A buffer layer 104 may be formed on the light blocking layer 102, the first capacitor electrode, the pad 128, the data line DL, the power line PL, and the reference line RL and over the entire surface of the substrate 120. The buffer layer 104 may include a first layer of silicon nitride (SiNx) as a lower layer and a second layer of silicon oxide (SiOx) as an upper layer.

A second capacitor electrode (not shown) may be disposed on the buffer layer 104 corresponding to the first capacitor electrode (not shown). A semiconductor layer 103 may be disposed on the buffer layer 104 corresponding to the light blocking layer 102. The semiconductor layer 103 may include an oxide semiconductor material such as indium-gallium-zinc oxide (IGZO).

A gate insulating layer 105 may be disposed on a central portion and both side portions of the semiconductor layer 103, and on the buffer layer 104 in boundary portions between up and down sub-pixels.

The gate insulating layer 105 may include semiconductor contact holes exposing both side portions of the semiconductor layer 103. The gate insulating layer 105 may include an inorganic insulating material such as silicon oxide (SiOx) or silicon nitride (SiNx).

Both side portions of the semiconductor layer 103 exposed through the semiconductor contact holes of the gate insulating layer 105 may be conductorized to operate as a source region and a drain region, and the central portion of the semiconductor layer 103 covered with the gate insulating layer 105 may operate as a channel region.

The second capacitor electrode (not shown) may be made into a conductor.

A gate electrode 107 may be disposed on the gate insulating layer 105 corresponding to the central portion of the semiconductor layer 103. A source electrode 109a and a drain electrode 109b may be respectively disposed on the gate insulating layer 105 corresponding to both side portions of the semiconductor layer 103.

In this case, at the boundary portions between sub-pixels neighboring in the same column (e.g., vertical direction), the gate line GL and the sensing line SL may be disposed along a horizontal direction.

The source and drain electrodes 109a and 109b may be in contact with both the side portions of the semiconductor layer 103 through the semiconductor contact holes, respectively. The source electrode 109a may be in contact with the light blocking layer 102 through a first contact hole PH1.

Each of the gate electrode 107 and the source and drain electrodes 109a and 109b may be formed of a single layer or multiple layers. When the gate electrode 107 and the source and drain electrodes 109a and 109b are formed of a single layer, the gate electrode 107 and the source and drain electrodes 109a and 109b may be made of one selected from a group consisting of molybdenum (Mo), aluminum (Al), chromium (Cr), gold (Au), titanium (Ti), nickel (Ni), neodymium (Nd), copper (Cu) and an alloy thereof.

In addition, when the gate electrode 107 and the source and drain electrodes 109a and 109b are formed of multiple layers, the gate electrode 107 and the source and drain electrodes 109a and 109b may be formed of at least one selected from a group consisting of molybdenum (Mo), aluminum (Al), chromium (Cr), gold (Au), titanium (Ti), nickel (Ni), neodymium (Nd), copper (Cu) and an alloy thereof. For example, the gate electrode 107 may be formed of double layers of molybdenum/aluminum-neodymium or molybdenum/aluminum.

In addition, the source and drain electrodes 109a and 109b may be formed of double layers of molybdenum/aluminum-neodymium, triple layers of titanium/aluminum/titanium, molybdenum/aluminum/molybdenum, or molybdenum/aluminum-neodymium/molybdenum.

The gate electrode 107, the source and drain electrodes 109a and 109b, and the semiconductor layer 103 may form a driving thin film transistor Tdr, and the first and second capacitor electrodes (not shown) may form the storage capacitor Cst.

The switching thin film transistor Tsw and the sensing thin film transistor Tse may have the same structure as the driving thin film transistor Tdr.

A gate electrode of the switching thin film transistor Tsw may be connected to the gate line GL, a source electrode of the switching thin film transistor Tsw may be connected to the data line DL, and a drain electrode of the switching thin film transistor Tsw may be connected to the gate electrode 107 of the driving thin film transistor Tdr.

The source electrode 109a of the driving thin film transistor Tdr may be connected to an anode 111 of the light emitting diode E, and the drain electrode 109b of the driving thin film transistor Tdr may be connected to the power line PL.

Although not shown in the drawings, a gate electrode of the sensing thin film transistor Tse may be connected to the sensing line SL, and a source electrode of the sensing thin film transistor Tse may be connected to the anode 111 of the light emitting diode E, and a drain electrode of the sensing thin film transistor Tse may be connected to the reference line RL.

A passivation layer 106 may be disposed on the switching thin film transistor Tsw, the driving thin film transistor Tdr, and the sensing thin film transistor Tse and over the entire surface of the substrate 120.

The passivation layer 106 may include an inorganic insulating material such as silicon oxide (SiOx) or silicon nitride (SiNx).

A color filter layer 160 may be disposed on the passivation layer 106 of the emission area EA of each of the sub-pixels R-SP, W-SP, B-SP and G-SP of the display area DA.

The color filter layer 160 may include red, blue, and green color filter layers respectively disposed on the passivation layer 106 of the emission areas of the red, green and blue sub-pixels R-SP, G-SP and B-SP among the plurality of sub-pixels R-SP, W-SP, B-SP and G-SP. A color filter layer may be omitted on the passivation layer 106 of the emission area EA of the white sub-pixel W-SP.

First and second overcoat layers 210 and 220 may be disposed on the color filter layer 160 and the passivation layer 106 and over the entire surface of the substrate 120. The first and second overcoat layers 210 and 220 may include an organic insulating material such as photoacrylic.

The first and second overcoat layers 210 and 220 and the passivation layer 106 may include a second contact hole PH2 exposing the source electrode 109a.

The anode 111 may be disposed on the second overcoat layer 220, and the anode 111 may be in contact with the source electrode 109a through the second contact hole PH2.

A bank layer 119 may be disposed on the anode 111. The bank layer 119 may include an opening exposing the anode 111 corresponding to the emission area EA of each of the sub-pixels R-SP, W-SP, B-SP and G-SP of the display area DA.

An organic light emitting layer 113 may be disposed on the anode 111 exposed through the opening of the bank layer 119, and a cathode 115 may be disposed on the organic light emitting layer 113 and over the entire surface of the substrate 120.

The anode 111, the organic light emitting layer 113 , and the cathode 115 may form the light emitting diode E.

Here, the anode 111 may be an electrode providing holes to the organic light emitting layer 113, and may include indium zinc oxide (ITO) having a relatively high work function. The cathode 115 may be an electrode providing electrons to the organic light emitting layer 113, and may include aluminum (Al) or magnesium silver (MgAg) having a relatively low work function.

The organic light emitting layer 113 may include a hole injecting layer, a hole transporting layer, an emitting material layer, an electron transporting layer, and an electron injecting layer.

A protective film 130 in a form of a thin film may be located over the driving thin film transistor Tdr and the light emitting diode E. Then, a face seal 131 may be located between the light emitting diode E and the protective film 130, and may be made of an organic or inorganic material being transparent and having adhesive property. By bonding the protective film 130 and the substrate 120 through the face seal 131, the organic light emitting diode display 100 may be encapsulated.

Here, the protective film 130 may be used by laminating at least two inorganic protective films in order to prevent external oxygen and moisture from penetrating into the organic light emitting diode display 100. At this time, an organic protective film may be preferably interposed between the two inorganic protective films to supplement an impact resistance of the inorganic protective films.

In the structure in which such the organic protective film and the inorganic protective film are alternately and repeatedly laminated, to prevent moisture and oxygen from penetrating through a side of the organic protective film, it is preferable that the inorganic protective film completely encloses the organic protective film.

Accordingly, the organic light emitting diode display 100 may prevent or at least reduce moisture and oxygen from penetrating into the organic light emitting diode display 100 from the outside.

As the organic light emitting diode display 100 according to the embodiment of the present disclosure is a bottom emission type, a light emitted from the organic light emitting layer 113 passes through the substrate 120 and is transmitted to the user, thereby displaying an image.

Here, in the organic light emitting diode display 100 according to the embodiment of the present disclosure, as shown in FIG. 3, a surface of the first overcoat layer 210 may have a plurality of concave portions 118 and a plurality of convex portions 117, which are alternately arranged, to form micro lenses ML.

Here, the convex portion 117 may have a structure that defines or surrounds each concave portion 118. The convex portion 117 may include a bottom portion 117a, a top portion 117b, and a side surface portion 117c.

Here, the side surface portion 117c may be a region including a maximum slope Smax of the convex portion 117 and may be an entire inclined surface forming the top portion 117b.

At this time, an inclination θ formed between a tangent C1 of the side surface portion 117c and a horizontal plane (i.e., the bottom portion 117a) may be 20 to 60 degrees in one embodiment. When the inclination θ is less than 20 degrees, since a light propagation angle by the micro lens ML is not significantly different from that of an organic light emitting diode display in which the first overcoat layer 210 is flat, there is little improvement in efficiency.

In addition, when the inclination θ exceeds 60 degrees, a light propagation angle is formed to be greater than a total reflection angle between the substrate 120 and an air layer outside the substrate 120, so that an amount of a light trapped inside the organic light emitting diode display is greatly increased. Thus, an efficiency is lower than that of the organic light emitting diode display in which the first overcoat layer 210 is flat.

As described above, as the inclination θ between the tangent C1 of the side surface portion 117c and the horizontal plane (i.e., the bottom portion 117a) is defined as 20 to 60 degrees, each of the concave portion 118 and the top portion 117b may be defined as a region in which the inclination θ formed between the tangent line C1 thereof and the horizontal plane (i.e., the bottom portion 117a) is less than 20 degrees, and the side surface portion 117c may be defined as a region in which the inclination θ between the tangent line C1 thereof and the horizontal plane (i.e., bottom portion 117a) is 20 degrees or more.

The convex portion 117 of the first overcoat layer 210 may have the pointed top portion 117b in order to further increase a light extraction efficiency of the organic light emitting layer 113. The convex portion 117 may have a triangular cross-sectional structure including a vertex corresponding to the top portion 117b, a base corresponding to the bottom portion 117a, and a hypotenuse corresponding to the side surface portion 117c.

A propagation path of a light emitted from the organic light emitting layer 113 may be changed toward the substrate 120 through the convex portion 117, so that the organic light emitting diode display 100 according to the embodiment of the present disclosure can improve a light extraction efficiency.

The second overcoat layer 220 positioned on the first overcoat layer 210 including the micro lenses ML may cover the micro lenses ML of the first overcoat layer 210 to have a flat surface.

Here, the anode 111 , the organic light emitting layer 113 , and the cathode 115 sequentially positioned over the second overcoat layer 220 may be all formed to be flat along the flat surface of the second overcoat layer 220.

Accordingly, as the organic light emitting layer 113 may be formed to have a uniform thickness for each of the sub-pixels R-SP, W-SP, B-SP and G-SP, an emission characteristic can also be uniform for each sub-pixel. Through this, an efficiency of the organic light emitting layer 113 for each region within each sub-pixel can be improved, and a lifetime can also be improved.

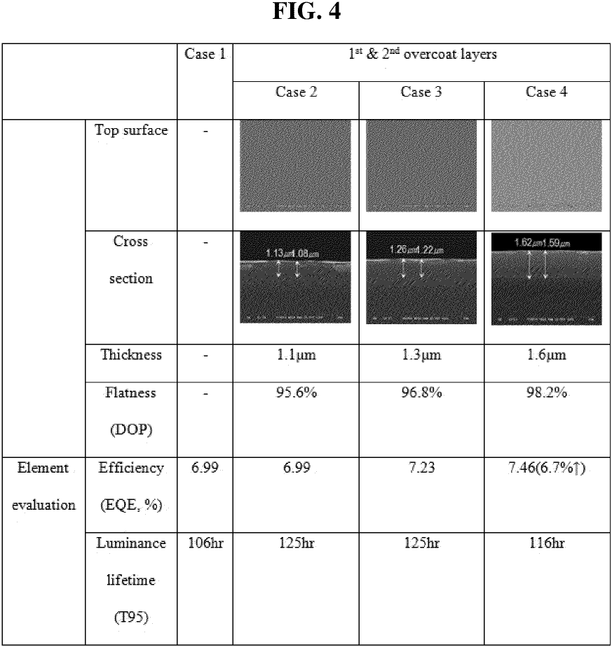

FIG. 4 shows an experimental result of measuring a light extraction efficiency and a lifetime according to presence or absence of the second overcoat layer 220 on the first overcoat layer 210 provided with the micro lens ML. Case 1 indicates a configuration in which a light emitting diode E is positioned directly on a first overcoat layer 210 having a micro lens ML, and case 2 indicates a configuration in which a second overcoat layer 220 having a thickness of 1.1um covers a micro lens ML of a first overcoat layer 210 to have a flat surface.

Case 3 indicates a configuration in which a second overcoat layer 220 having a thickness of 1.3 µm covers a micro lens ML of a first overcoat layer 210 to have a flat surface, and case 4 indicates a configuration in which a second overcoat layer 220 having a thickness of 1.6 µm covers a micro lens ML of a first overcoat layer 210 to have a flat surface.

Here, a luminance lifetime T95 indicates a time taken until a luminance of an arbitrarily set reference sub-pixel among sub-pixels R-SP, W-SP, B-SP and G-SP becomes 95% of an initial luminance, and is defined as a target luminance lifetime. For example, the target luminance lifetime may be determined based on a red sub-pixel R-SP having the best luminance lifetime per unit area. In this case, the luminance lifetime T95 may be defined as a time it takes for a luminance of a red sub-pixel R-SP that emits light with 255 grayscales to become 95% of an initial luminance.

As seen from FIG. 4, case 2, 3, and 4 all have improved luminance lifetime of an element compared to case 1. Accordingly, compared to case 1 that the micro lens ML is provided in the first overcoat layer 210, further forming the second overcoat layer 220 covering the microlens ML on the first overcoat layer 210 to have a flat surface can further improve the luminance life of the light emitting diode E.

In addition, in FIG. 4, it is seen that case 3 and case 4 also improve an efficiency of the element. The efficiency is a measure of an external quantum efficiency (EQE), and the external quantum efficiency (EQE) may be defined as a product of an internal quantum efficiency (IQE) and a light extraction efficiency.

In particular, it is seen that the efficiency of case 4 is further improved by 6.7% compared to that of case 1.

Through this, as compared to the case 1 in which the micro lens ML is provided in the first overcoat layer 210, further forming the second overcoat layer 220 having a flat surface by covering the micro lens ML on the first overcoat layer 210 can further improve the efficiency of the light emitting diode E.

Meanwhile, it is seen that there is no difference in efficiency between case 1 and case 2. This is because when the thickness of the second overcoat layer 220 is 1.1 µm, the flatness is low and thus an effect by the second overcoat layer 220 is difficult to expect.

Therefore, in one embodiment the second overcoat layer 220 has a thickness of at least 1.2 µm or more. In addition, even if the second overcoat layer 220 has a thickness of 1.6 µm, the flatness is 98.2%, which is close to 100%, so that in consideration of efficiencies of materials and processes, the second overcoat layer 220 is formed to have a thickness of 1.8 µm or less in one embodiment. That is, the second overcoat layer 220 is formed to have a thickness in a thickness range of 1.2 µm ~ 1.8 µm in one embodiment.

In particular, in the organic light emitting diode display 100 according to the embodiment of the present disclosure, by forming the second overcoat layer 220 having a flat surface on the first overcoat layer 210 including the micro lens ML to cover the first overcoat layer 210, while improving a light extraction efficiency as described above, an occurrence of rainbow mura can also be reduced.

Here, the rainbow mura may be generated through a reflection visibility due to an interference of visible light as a light emitted from each organic light emitting layer 113 is refracted through a curved surface and a path of the light is changed. According to the organic light emitting diode display 100 according to the present disclosure, as the organic light emitting layer 113 is positioned on the second overcoat layer 220 having a flat surface, the occurrence of the rainbow mura can be minimized.

FIG. 5A is a picture of measuring a rainbow mura of a general organic light emitting diode display, and FIG. 5B is a picture of measuring a rainbow mura of an organic light emitting diode display according to an embodiment of the present disclosure.

Referring to FIGS. 5A and 5B, it is seen that a rainbow stain is clearly displayed in FIG. 5A. In contrast, in FIG. 5B, it is seen that a rainbow stain is hardly recognized.

Thus, the organic light emitting diode display 100 according to the embodiment of the present disclosure can reduce the rainbow mura by reducing a reflection visibility.

In addition, by reducing the reflection visibility, it is possible to reduce an occurrence of a high reflectance, and thus, a deterioration of a visibility of black color can also be minimized.

TABLE 1

| Measurement of Reflection | case A | case 1 | case 4 |
|---|---|---|---|
| Specular | 1.0 | 1.0 | 1.0 |
| Diffuse | 0.15 | 0.48 | 0.15 |
| Haze | 0.06 | 0.06 | 0.06 |
| Lambertian | 0.09 | 0.42 | 0.09 |
| Matrix scatter | 0.007 | 0.084 | 0.006 |

The Table 1 is an experimental result of measuring a visibility of black color. Case A indicates a configuration of a general organic light emitting diode display without a micro lens, which is further provided with a polarizing plate for minimizing an external light reflection on an outer surface of a substrate. Case 1 has the same configuration as case 1 in FIG. 4, and case 4 also has the same configuration as case 4 in FIG. 4.

Prior to explanation, in Table 1, “Specular” means a specular reflection, “Diffuse” means a diffuse reflection, “Lambertian” means a reflection visibility of a black color, and “Matrix scatter” means a rainbow mura.

Looking at the Table 1, it is seen that a Matrix scatter value of case 4 is less than a Matrix scatter value of case 1. Since the Matrix scatter means a rainbow mura, according to the experimental results, by forming the second overcoat layer 220 having a flat surface on the first overcoat layer 210 including the micro lens ML to cover the first overcoat layer 210 as in the embodiment of the present disclosure, an occurrence of a rainbow mura can also be reduced.

In particular, in the Table 1, it is seen that a Lambertian of case 4 is significantly less than a Lambertian of case 1. As the Lambertian means a Lambertian reflection, a high Lambertian reflection means a high reflectance. Therefore, it means that case 1 having a higher Lambertian has a greater reflectance than case 4, which also means that a visibility of a black color of case 1 is low.

On the other hand, it is seen that case 4 has the same Lambertian as case A which is a general organic light emitting diode display provided with a polarizing plate for an external light reflection. Through this, by forming the second overcoat layer 220 having a flat surface on the first overcoat layer 210 including the micro lens ML to cover the first overcoat layer 210, it is possible to reduce a reflection visibility and thus to minimize an occurrence of a high reflectance.

Through this, it is seen that a deterioration of a visibility of a black color can also be minimized.

In this case, the second overcoat layer 220 and the first overcoat layer 210 have different refractive indices, and a refractive index of the second overcoat layer 220 is greater than a refractive index of the first overcoat layer 210.

Here, in the case of the embodiment of the present disclosure, the second overcoat layer 220 located below the anode 111 may be formed of a high refractive index material having a refractive index approximate (or similar) to a refractive index of the anode 111 so as to match a refractive index with the anode 111. Accordingly, it is possible to prevent or at least reduce a total reflection due to a difference in refractive index between the two media i.e., the anode 111 and the second overcoat layer 220.

That is, as the refractive index of the transparent anode 111 made of ITO is about 1.7 to 1.8, in one embodiment a high refractive index material having a refractive index improved to 1.57 to 1.8 is applied to the second overcoat layer 220 so as to match the refractive index with the anode 111 and thus a total reflection at a boundary between the anode 111 and the second overcoat layer 220 is prevented.

As such, when the second overcoat layer 220 is formed to have a high refractive index of 1.57 to 1.8, the first overcoat layer 210 has a refractive index of 1.43 to 1.57 in one embodiment.

Therefore, a propagation path of a light, which is emitted from the organic light emitting layer 113 and is not extracted to an outside due to repeated total reflection inside the first and second overcoat layers 210 and 220, can be changed toward the substrate 120.

That is, the first overcoat layer 210 has a refractive index approximate (or similar) to a refractive index of the passivation layer 106 in order to prevent or at least reduce total reflection due to a difference in refractive index between the first overcoat layer 210 and the passivation layer 106 there below, so that the first overcoat layer 210 has a refractive index of 1.43 to 1.57 in one embodiment.

On the other hand, when the first overcoat layer 210 has a refractive index of 1.43 to 1.57, when a light is emitted from the organic light emitting layer 113 positioned on the flat surface of the second overcoat layer 220, the light passes through the second overcoat layer 220 and is incident on the first overcoat layer 210. At this time, as the refractive index of the second overcoat layer 220 is higher than that of the first overcoat layer 210, when an incident angle of the light is greater than a total reflection critical angle, the light is not emitted to the outside but is absorbed into the element due to an internal total reflection phenomenon.

However, the organic light emitting diode display 100 according to the embodiment of the present disclosure includes the micro lenses ML at the surface of the first overcoat layer 210. Accordingly, among a light emitted from the organic light emitting layer 113, a light that, which would be continuously totally reflected and trapped inside the organic light emitting diode display 100, proceeds at an angle that is less than a total reflection critical angle by the micro lenses ML of the first overcoat layer 210 and is extracted to the outside through multiple reflections.

Accordingly, since an emission efficiency to the outside is increased, a light extraction efficiency of the organic light emitting diode display 100 can be improved.

In summary, in the organic light emitting diode display 100 according to the embodiment of the present disclosure, the first and second overcoat layers 210 and 220 having different refractive indices are stacked on each other, the first overcoat layer 210 includes the micro lenses ML, and the second overcoat layer 220 covers the micro lens ML to be planarized, thereby improving a light extraction efficiency and minimizing an occurrence of rainbow mura.

In addition, by reducing an occurrence of high reflectance, deterioration of a visibility of a black color is minimized, and thus a contrast ratio is improved.

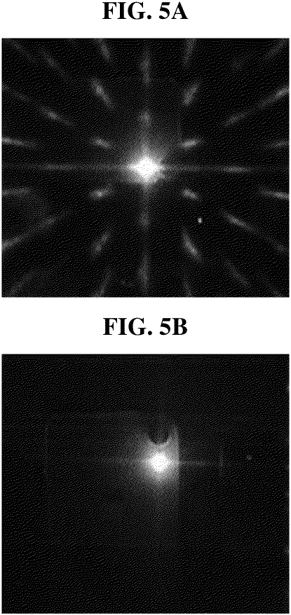

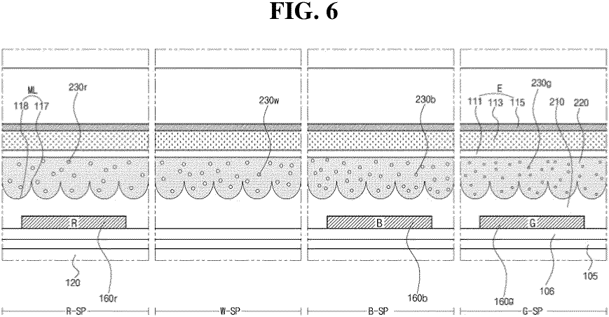

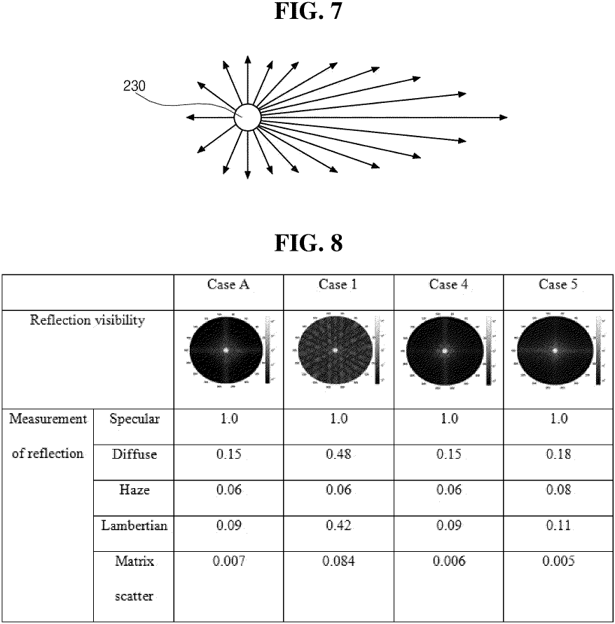

FIG. 6 is a cross-sectional view, taken along a line V-V’ of FIG. 1, schematically illustrating sub-pixels according to an embodiment of the present disclosure, and FIG. 7 is a schematic view illustrating a state in which a light is scattered by a high refractive particle according to one embodiment.

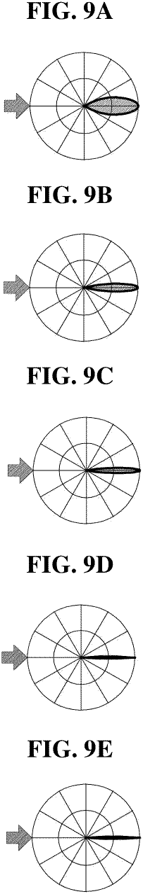

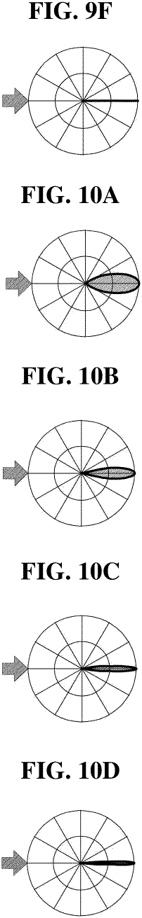

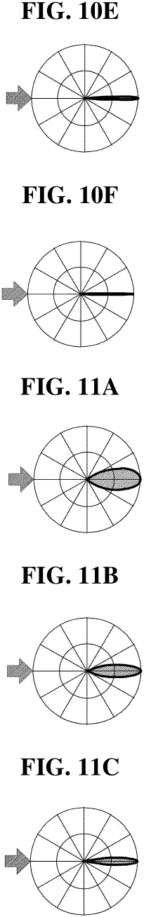

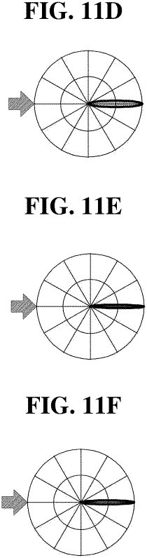

FIGS. 9A to 9F are graphs simulating a Mie-scattering effect of a high refractive particle for a blue light according to one embodiment, FIGS. 10A to 10F are graphs simulating a Mie-scattering effect of a high refractive particle for a green light according to one embodiment, and FIGS. 11A to 11F are graphs simulating a Mie-scattering effect of a high refractive particle for a red light according to one embodiment.

As shown in FIG. 6, in the organic light emitting diode display 100 according to the embodiment of the present disclosure, a plurality of sub-pixels R-SP, W-SP, B-SP and G-SP are defined over a substrate 120. A gate insulating layer 105 and a passivation layer 106 may be positioned over the substrate 120. A red color filter layer 160r may be disposed on the passivation layer 106 of the red sub-pixel R-SP, and a green color filter layer 160g may be disposed on the passivation layer 106 of the green sub-pixel G-SP.

In addition, a blue color filter layer 160b may be disposed on the passivation layer 106 of the blue sub-pixel B-SP. A color filter layer may be omitted over the passivation layer 106 of the white sub-pixel W-SP.

A first overcoat layer 210 may be disposed on the color filter layers 160r, 160g and 160b and the passivation layer 106 and over the entire surface of the substrate 120. The first overcoat layer 210 may have a plurality of concave portions 118 and a plurality of convex portions 117 alternately arranged to form micro lenses ML.

As described above, in the organic light emitting diode display (100 of FIG. 2) according to the embodiment of the present disclosure, the micro lens ML may be formed at the first overcoat layer 210. Accordingly, by changing a path of a light, which would not be extracted to an outside due to repeated total reflection inside the organic light emitting diode display (100 of FIG. 2), toward the substrate 120, a light extraction efficiency can be improved.

The second overcoat layer 220 may be positioned on the first overcoat layer 210 including the micro lenses ML. The second overcoat layer 220 may cover the micro lenses ML of the first overcoat layer 210 to have a flat surface.

An anode 111, an organic light emitting layer 113, and a cathode 115 sequentially positioned on the second overcoat layer 220 may be all formed to be flat along the flat surface of the second overcoat layer 220.

Accordingly, as the organic light emitting layer 113 is formed to have a uniform thickness for each of the sub-pixels R-SP, W-SP, B-SP and G-SP, an emission characteristic can also be uniform for each of the sub-pixels R-SP, W-SP, B-SP and G-SP. Accordingly, an efficiency of the organic light emitting layer 113 for each region within each of the sub-pixels R-SP, W-SP, B-SP and G-SP is improved, and a lifetime can also be improved.

Here, in the organic light emitting diode display (100 of FIG. 2) according to the embodiment of the present disclosure, high refractive particles 230 (also referred to as refractive particles) may be further included and dispersed in the second overcoat layer 220. The high refractive particles 230 may be particles having a refractive index different from that of the second overcoat layer 220, and the high refractive particles 230 may not be particularly limited as long as they are particles capable of scattering incident light. In one embodiment, the high refractive particles have a refractive index that is greater than the refractive index of the second overcoat layer 220.

As such, by further containing the high refractive particles 230 in the second overcoat layer 220, the organic light emitting diode display (100 in FIG. 2) can further reduce an occurrence of a rainbow mura by further reducing a reflection visibility, and can also minimize an occurrence of high reflectance. Accordingly, it is also possible to minimize a deterioration of a visibility of a black color.

The following Table 1 shows experimental results of measuring a rainbow mura and a visibility of a black color. Case A indicates a configuration of a general organic light emitting diode display without a micro lens, which is provided with a polarizing plate for preventing an external light reflection on an outer surface of a substrate.

Case 1 has the same configuration as case 1 in FIG. 4 and Table 1, and case 4 has the same configuration as case 4 in FIG. 4 and Table 1.

Case 5 indicates a configuration in which the second overcoat layer 220 having the high refractive particles 230 dispersed therein covers the micro lenses ML of the first overcoat layer 210 to have a flat surface.

As seen in FIG. 8, a Matrix scatter value of case 5 is less than that of Case 4. Since the Matrix scatter means a rainbow mure, the second overcoat layer 220 having a flat surface on the first overcoat layer 210 including the micro lens ML and containing the high refractive particles 230 dispersed therein is located to cover the first overcoat layer 210 as in the embodiment of the present disclosure, an occurrence of a rainbow mura can be further reduced. In particular, in FIG. 8, it is seen that a Lambertian of case 5 is lower than that of case 4, which also means that a visibility of a black color of case 5 is lower than that of case 4.

Through this, by forming the second overcoat layer 220 having a flat surface on the first overcoat layer 210 including the micro lens ML to cover the first overcoat layer 210, it is possible to reduce a reflection sensibility. In this case, by dispersing the high refractive particles 230 in the second overcoat layer 220, the reflection visibility can be further reduced.

Therefore, it is possible to prevent or at least reduce an occurrence of a high reflectance, and thus, it is possible to further prevent a deterioration of a visibility of a black color.

Here, the high refractive particle 230 may have a microscopic size (e.g., a diameter) of several hundred nanometers to several micrometers, and may have a size (e.g., diameter) at which a Mie-scattering occurs in response to a wavelength of a light emitted from each of the sub-pixels R-SP, W-SP, B-SP and G-SP according to one embodiment. In one embodiment, the wavelength is a predetermined wavelength of light that corresponds to the wavelength of light emitted by each sub-pixel.

Specifically, as a scattering refers to a phenomenon in which a light collides with a specific particle and scatters in various directions, the scattering refers to a phenomenon in which a wave or high-speed beam collides with many molecules, atoms, or fine particles to change a direction of motion and scatter. This occurs in gases, liquids and solids, but in solids or liquids, scattered light is synthesized and appears as refracted or reflected light more often.

A representative scattering may be largely divided into a Rayleigh scattering and a Mie-Scattering. The Rayleigh scattering refers to a scattering that occurs when a size of a particle that cause a scattering is very small and smaller than a wavelength of light, and in this case, a forward scattering in which a light is scattered in a propagation direction and a backward scattering in which a light is scattered in a reflection direction occur similarly.

In contrast, as shown in FIG. 7, the Mie-scattering occurs when a size of a specific particle 230 colliding with a light is similar to a wavelength of the light. That is, when a diameter of the particle 230 is ⅒ or more of a wavelength of a light, the Mie-scattering occurs where a forward scattering is overwhelmingly more common than a backward scattering.

This Mie-scattering causes a main scattering to occur in the same direction as an incident direction of the light, thereby further improving an efficiency of light extracted forward.

Accordingly, the organic light emitting diode display (100 of FIG. 2) according to an embodiment of the present disclosure is configured to cause the Mie-scattering in which the forward scattering occurs most through the high refractive particles 230 dispersed in the second overcoat layer 220.

To this end, the high refractive particles 230 have a spherical shape and are configured to have a size corresponding to a wavelength of a visible light region, so that the high refractive particles 230 allow a light emitted from each of the sub-pixel R-SP, W-SP, B-SP and G-SP to be scattered forward.

The high refractive particles 230 may include, for example, an organic material such as polystyrene or a derivative thereof, an acrylic resin or a derivative thereof, a silicone resin or a derivative thereof, or a novolac resin or a derivative thereof, or an inorganic material such as silica, alumina, titanium oxide or zirconium oxide.

In addition, the high refractive particles 230 may include any one of the above materials, or may include two or more materials of the above materials. The high refractive particle 230 may be formed of a core/cell type particle or hollow particle if necessary.

Here, a size of the high refractive particle 230 is 0.1µmto 2 µm to be similar to a wavelength of a visible light region in one embodiment. Accordingly, by maximizing an effect of the Mie-Scattering through a light emitted from each of the sub-pixels R-SP, W-SP, B-SP and G-SP, a light emitted from each of the sub-pixels R-SP, W-SP, B-SP and G-SP to the high refractive particles 230 can be forward scattered.

Meanwhile, in order to induce the Mie-scattering, the diameter of the high refractive particle 230 needs to be ⅒ or more of a corresponding light wavelength. Considering a wavelength of light emitted from each of the sub-pixels R-SP, W-SP, B-SP and G-SP is different, the high refractive particles 230 that overlap a corresponding one of the sub-pixels R-SP, W-SP, B-SP and G-SP may have different diameters. For example, the diameter of the high refractive particles 230 may be 70 nm or more in the case of the red sub-pixel R-SP, 55 nm or more in the case of the green sub-pixel G-SP, and 40 nm or more in the case of a blue sub-pixel B-SP in one embodiment.

However, it is not only a very difficult task to actually make a small high refractive particle 230 having a diameter of 40 nm to 70 nm, but as described above, the larger the diameter of the high refractive particles 230 is, the more forward scattering desired in the present disclosure increases. Thus, considering a difficulty of manufacturing and an effect of a forward scattering, the high refractive particle 230 have a diameter of 150 nm or less.

However, if the diameter is too large, the thickness of the second overcoat layer 220 in which the high refractive particles 230 are dispersed may be too thick to increase an opacity. Thus, a maximum size of the high refractive particle 230 is 4000 nm or less i.e., 4 µm or less in diameter in one embodiment.

FIGS. 9A to 9F are graphs simulating a Mie-scattering effect of a high refractive particle for a blue light according to one embodiment, FIGS. 10A to 10F are graphs simulating a Mie-scattering effect of a high refractive particle for a green light according to one embodiment, and FIGS. 11A to 11F are graphs simulating a Mie-scattering effect of a high refractive particle for a red light according to one embodiment.

In FIGS. 9A to 9F, 10A to 10F, and 11A to 11F, a light is incident in a direction of an arrow shown, and in this case, and when a light is scattered adjacent to a horizontal line of the graphs, it means that a forward scattering effect is large.

FIGS. 9A to 9F are based on 450 nm, which is a main wavelength band of a blue light. FIG. 9A is a case in which the diameter of the high refractive particle that overlaps a blue sub-pixel B-SP is 0.5 µm, FIG. 9B is a case in which the diameter of the high refractive particle that overlaps a blue sub-pixel B-SP is 1.0 µm, and FIG. 9C is a case in which the diameter of the high refractive particle that overlaps a blue sub-pixel B-SP is 1.5um.

FIG. 9D is a case in which the diameter of the high refractive particle that overlaps a blue sub-pixel B-SP is 2.0um, FIG. 9E is a case in which the diameter of the high refractive particle that overlaps a blue sub-pixel B-SP is 2.5um, and FIG. 9F is a case in which the diameter of the high refractive particle that overlaps a blue sub-pixel B-SP is 3.0um. In the blue light, when the diameter of the high refractive particle is 2.0um or more, the forward scattering effect is greatly exhibited.

FIGS. 10A to 10F are based on 550 nm, which is a main wavelength band of a green light. FIG. 10A is a case in which the diameter of the high refractive particle that overlaps a green sub-pixel G-SP is 0.5 µm, FIG. 10B is a case in which the diameter of the high refractive particle that overlaps a green sub-pixel G-SP is 1.0 µm, and FIG. 10C is a case in which the diameter of the high refractive particle that overlaps a green sub-pixel G-SP is 1.5um.

FIG. 10D is a case in which the diameter of the high refractive particle that overlaps a green sub-pixel G-SP is 2.0um, FIG. 10E is a case in which the diameter of the high refractive particle that overlaps a green sub-pixel G-SP is 2.5um, FIG. 10F is a case in which the diameter of the high refractive particle that overlaps a green sub-pixel G-SP is 3.0um. In the green light, when the diameter of the high refractive particle is 2.5 µm, the forward scattering effect is greatly exhibited.

In addition, FIGS. 11A to 11F are based on 650 nm, which is a main wavelength band of a red light. FIG. 11A is a case in which the diameter of the high refractive particle that overlaps a red sub-pixel R-SP is 0.5um, FIG. 11B is a case in which the diameter of the high refractive particle that overlaps a red sub-pixel R-SP is 1.0um, and FIG. 11C is a case in which the diameter of the high refractive particle that overlaps a red sub-pixel R-SP is 1.5um.

FIG. 11D is a case in which the diameter of the high refractive particle that overlaps a red sub-pixel R-SP is 2.0um, FIG. 11E is a case in which the diameter of the high refractive particle that overlaps a red sub-pixel R-SP is 2.5um, and FIG. 11F is a case in which the diameter of the high refractive particle that overlaps a red sub-pixel R-SP is 3.0um. In the red light, when the diameter of the high refractive particle is 3.0 µm, the forward scattering effect is greatly exhibited.

Accordingly, in the organic light emitting diode display (100 of FIG. 2) according to the embodiment of the present disclosure, the high refractive particles (or R high refractive particles or first refractive particles) having the diameter of 3.0 µm or more are dispersed in the second overcoat layer positioned to correspond to the red sub-pixel R-SP (e.g., overlapping the red sub-pixel SP), and in this case, the high refractive particles have the diameter of 3 µm to 4 µm in consideration of the thickness of the second overcoat layer according to one embodiment.

In the second overcoat layer positioned to correspond to the green sub-pixel G-SP (e.g., overlapping the green sub-pixel G-SP), the high refractive particles (or G high refractive particles or second refractive particles) having the diameter of 2.5 µm to 3 µm are dispersed in one embodiment. In the second overcoat layer positioned to correspond to the blue sub-pixel B-SP (e.g., overlapping the blue sub-pixel G-SP), the high refractive particles (or B high refractive particles or third refractive particles) having the diameter of 2.0 µm to 3.0 µm are dispersed in one embodiment.

Here, since the white light has a wavelength range of 400 nm to 800 nm, the white light may be set based on the red light, so that the high refractive particles (or W high refractive particles or fourth refractive particles) having the diameter of 3.0 µm or more are dispersed in the second overcoat layer corresponding to the white sub-pixel W-SP (e.g., overlapping the white sub-pixel W-SP) in one embodiment.

In summary, the diameters of the high refractive particles 230 are defined as follows: diameter of B high refractive particles < diameter of G high refractive particles < diameter R high refractive particles = diameter of W high refractive particles.

As such, the high refractive particles 230 are dispersed in the second organic light emitting layer 220 to have the diameters respectively corresponding to the wavelength bands of the lights emitted from the sub-pixels R-SP, W-SP, B-SP and G-SP. Accordingly, the effect of the Mie-scattering is maximized, and thus the efficiency of the light extracted forward is further improved.

Accordingly, the organic light emitting diode display (100 of FIG. 2) according to the embodiment of the present disclosure can further improve the light extraction efficiency.

As described above, in the organic light emitting diode display 100 according to the embodiment of the present disclosure, the first and second overcoat layers 210 and 220 having different refractive indices are stacked on each other, the first overcoat layer 210 includes the micro lenses ML, and the second overcoat layer 220 covers the micro lens ML to be planarized, thereby improving a light extraction efficiency and minimizing an occurrence of rainbow mura.

In addition, a deterioration of a visibility of a black color is minimized by minimizing an occurrence of high reflectance, and each of the sub-pixels R-SP, W-SP, B-SP and G-SP can have a uniform emission characteristic, thereby improving an efficiency of the organic light emitting layer 113 and also increasing a lifetime.

At this time, by dispersing the high refractive particles 230 in the second overcoat layer 220, an occurrence of a rainbow mura can be further reduced, and a deterioration of a visibility of a black color can also be reduced.

In particular, the high refractive particles 230 are dispersed in the second overcoat layer 220 to have the diameters respectively corresponding to the wavelength bands of the lights emitted from the sub-pixels R-SP, W-SP, B-SP and G-SP, thus an effect of the Mie-scattering is maximized, and thus an efficiency of the light extracted forward is further improved.

It will be apparent to those skilled in the art that various modifications and variation can be made in the present disclosure without departing from the spirit or scope of the disclosure. Thus, it is intended that the present disclosure cover the modifications and variations of this disclosure provided they come within the scope of the appended claims and their equivalents.

What is claimed is:

1. An organic light emitting diode display comprising:
a substrate including a plurality of sub-pixels, the plurality of sub-pixels comprising a red sub-pixel, a green sub-pixel, and a blue sub-pixel;
a thin film transistor on the substrate;
a first overcoat layer on the thin film transistor, the first overcoat layer including a plurality of micro lenses at a surface of the first overcoat layer;
a second overcoat layer on the first overcoat layer and having a flat surface, the second overcoat layer including refractive particles dispersed within the second overcoat layer; and
a light emitting diode on the second overcoat layer.

2. The organic light emitting diode display of claim 1, wherein the refractive particles have a diameter in which a Mie-Scattering occurs in response to a wavelength of light emitted from the light emitting diode.

3. The organic light emitting diode display of claim 1, wherein the refractive particles include first refractive particles that overlaps the red sub-pixel and the first refractive particles having a first diameter, second refractive particles that overlaps the green sub-pixel and the second refractive particles having a second diameter, and third refractive particles that overlaps the blue sub-pixel and the third refractive particles having a third diameter.

4. The organic light emitting diode display of claim 3, wherein the first diameter of a first refractive particle from the first refractive particles that overlaps the red sub-pixel is larger than the second diameter of a second refractive particle from the second refractive particles that overlaps the green sub-pixel and larger than the third diameter of a third refractive particle from the third refractive particles that overlaps the blue sub-pixel.

5. The organic light emitting diode display of claim 3, wherein the first diameter of a first refractive particle from the first refractive particles that overlaps the red sub-pixel is larger than the second diameter of a second refractive particle from the second refractive particles that overlaps the green sub-pixel, and
wherein the second diameter of the second refractive particle is larger than the third diameter of a third refractive particle from the third refractive particles that overlaps the blue sub-pixel.

6. The organic light emitting diode display of claim 5, wherein the first diameter is in a range of 3 µm to 4 µm, the second diameter is in a range of 2.5 µm to 3 µm, and the third diameter is in a range of 2 µm to 3 µm.

7. The organic light emitting diode display of claim 3, wherein the plurality of sub-pixels further comprise a white sub-pixel over the substrate and the refractive particles further include fourth refractive particles that overlap the white sub-pixel,
wherein a fourth refractive particle from the fourth refractive particles that overlap the white sub-pixel has a fourth diameter that is a same as the first diameter of a first refractive particle from the first refractive particles that overlap the red sub-pixel.

8. The organic light emitting diode display of claim 1, wherein the second overcoat layer has a refractive index that is different from a refractive index of the refractive particles.

9. The organic light emitting diode display of claim 1, wherein the refractive particles have a diameter of ⅒ of a wavelength of light emitted from each of the red sub-pixel, the green sub-pixel, and the blue sub-pixel.

10. The organic light emitting diode display of claim 1, wherein the refractive particles include at least one of polystyrene, acrylic resin, silicone resin, novolak resin, silica, alumina, titanium oxide, or zirconium oxide.

11. The organic light emitting diode display of claim 1, wherein the first overcoat layer has a refractive index that is less than a refractive index of the second overcoat layer.

12. The organic light emitting diode display of claim 11, wherein the refractive index of the first overcoat layer is in a range of 1.43 to 1.57, and the refractive index of the second overcoat layer is in a range of 1.57 to 1.8.

13. The organic light emitting diode display of claim 1, wherein the light emitting diode includes an anode on the second overcoat layer, an organic light emitting layer on the anode, and a cathode on the organic light emitting layer.

14. A display device comprising:
a substrate including a plurality of subpixels, the plurality of subpixels including a first subpixel configured to emit light of a first color, a second subpixel configured to emit light of a second color, and a third subpixel configured to emit light of a third color;
a thin film transistor on the substrate;
a first overcoat layer on the thin film transistor;
a second overcoat layer on the first overcoat layer, the second overcoat layer including refractive particles dispersed within the second overcoat layer; and
a light emitting diode on the second overcoat layer,
wherein the refractive particles include first refractive particles that overlap the first sub-pixel and have a first diameter, second refractive particles that overlap the second sub-pixel and have a second diameter, and third refractive particles that overlaps the third sub-pixel and have a third diameter,
wherein at least one of the first diameter, the second diameter, and the third diameter is different from another one of the first diameter, the second diameter, and the third diameter.

15. The organic light emitting diode display of claim 14, wherein the first color is red, the second color is green, and the third color is blue.

16. The organic light emitting diode display of claim 14, wherein the first diameter of the first refractive particles that overlaps the first sub-pixel is larger than the second diameter of the second refractive particles that overlaps the second sub-pixel and larger than the third diameter of the third refractive particles that overlaps the third sub-pixel.

17. The organic light emitting diode display of claim 14, wherein the first diameter of the first refractive particles that overlaps the first sub-pixel is larger than the second diameter of the refractive particles that overlaps the second sub-pixel, and
wherein the second diameter of the second refractive particle is larger than the third diameter of the third refractive particles that overlaps the third sub-pixel.

18. The organic light emitting diode display of claim 17, wherein the first diameter is in a range of 3 µm to 4 µm, the second diameter is in a range of 2.5 µm to 3 µm, and the third diameter is in a range of 2 µm to 3 µm.

19. The organic light emitting diode display of claim 14, wherein the plurality of sub-pixels further comprise a fourth sub-pixel over the substrate that emits light of a fourth color and the refractive particles further include fourth refractive particles that overlap the fourth sub-pixel,
wherein the fourth refractive particles that overlap the fourth sub-pixel has a fourth diameter that is a same as the first diameter of the first refractive particles that overlap the first sub-pixel.

20. The organic light emitting diode display of claim 14, wherein the second overcoat layer has a refractive index that is different from a refractive index of the refractive particles.

21. The organic light emitting diode display of claim 14, wherein the refractive particles have a diameter of ⅒ of a wavelength of light emitted from each of the first sub-pixel, the second sub-pixel, and the third sub-pixel.

22. The organic light emitting diode display of claim 14, wherein the refractive particles include at least one of polystyrene, acrylic resin, silicone resin, novolak resin, silica, alumina, titanium oxide, or zirconium oxide.

23. The display device of claim 14, wherein a surface of the first overcoat layer includes a plurality of micro lenses.

24. The organic light emitting diode display of claim 23, wherein the first overcoat layer has a refractive index that is less than a refractive index of the second overcoat layer.

25. The organic light emitting diode display of claim 23, wherein the refractive index of the first overcoat layer is in a range of 1.43 to 1.57, and the refractive index of the second overcoat layer is in a range of 1.57 to 1.8.
